(19) United States
(12) Patent Application Publication
(10) Pub. No.: US 2013/0176058 A1
(43) Pub. Date: Jul. 11, 2013

(54) VOLTAGE COMPARISON CIRCUIT

(71) Applicant: LAPIS SEMICONDUCTOR CO., LTD., Tokyo (JP)

(72) Inventor: Yosuke IWASA, Tokyo (JP)

(73) Assignee: LAPIS SEMICONDUCTOR CO., LTD., Tokyo (JP)

(21) Appl. No.: 13/720,989

(22) Filed: Dec. 19, 2012

(30) Foreign Application Priority Data
Dec. 29, 2011 (JP) 2011-290414

(51) Int. Cl. H03K 5/24

(52) U.S. Cl. CPC H03K 5/2481
USPC 327/81

(57) ABSTRACT

There is provided a voltage comparison circuit including: a voltage adjustment section connected between a first potential supply line and a first node; a first constant current source connected between the first node and a fixed potential supply line; a switch element connected between a second potential supply line and a second node, and including a control terminal connected to the first node, the switch element operating in accordance with a voltage of the first node; and a second constant current source connected between the second node and the fixed potential supply line.

### CROSS-REFERENCE TO RELATED APPLICATION

This application is based on and claims priority under 35 USC 119 from Japanese Patent Application No. 2011-290414 filed on Dec. 29, 2011, the disclosure of which is incorporated by reference herein.

### BACKGROUND

1. Technical Field

The present invention relates to a voltage comparison circuit, and for example relates to a voltage comparison circuit capable of directly comparing various power source voltages.

2. Related Art

A voltage comparison circuit 60 as illustrated in FIG. 6 is commonly known as a voltage comparison circuit (a comparator). The voltage comparison circuit 60 combines a differential stage 62 with a grounded-source amplification stage 64. The differential stage 62 includes NMOS transistors 72 and 74, the sources of which are connected together. Voltages that are objects of comparison are inputted to the respective gates of the NMOS transistors 72 and 74.

However, in the voltage comparison circuit 60 as illustrated in FIG. 6, the respective gates of the NMOS transistors 72 and 74 serve as input terminals. Therefore, if a voltage exceeding the threshold voltage of the NMOS transistor 72 or the threshold voltage of the NMOS transistor 74 is inputted, a linear region is formed in the NMOS transistor 72 or 74, and the voltages may not be compared. Thus, a range of voltages that can be inputted to the voltage comparison circuit 60 is limited, and power source voltages such as VDD and the like may not be directly compared.

To compare power source voltages using the voltage comparison circuit 60, the power source voltages must be voltage-divided by resistors or the like, or a range of voltages that can be inputted to the voltage comparison circuit must be extended, or the like.

When a voltage is voltage-divided by resistors, the overall circuit area increases, and power consumption is greater because of the provision of the resistors. Moreover, variations in accuracy of the resistance components are likely to have an effect on comparison results.

To extend the range of voltages that can be inputted to a voltage comparison circuit, providing a level shifter stage or forming the differential stage of the voltage comparison circuit as a folded cascode amplification circuit have been considered.

However, providing a level shifter stage or forming the differential stage as a folded cascode amplification circuit increases the size of the circuit. Hence, power consumption increases, the effects of variations in components become greater, and the level of difficulty of circuit design rises.

Japanese Patent Application Laid-Open (JP-A) No. 2010-230508 discloses a battery voltage detection circuit that measures the voltage of a battery of approximately 3 V, and makes a determination as to whether the voltage of the battery is at least a predetermined threshold.

However, the battery voltage detection circuit recited in JP-A No. 2010-230508 is only applicable to voltages in a narrow range of about 1.5 V to 3 V, which are supplied from batteries used in watches. The problem of voltages that can be inputted to a voltage comparison circuit being limited has not been solved.

### SUMMARY

The present invention is proposed to solve the problem described above, and an object of the present invention is to provide a voltage comparison circuit, particularly a voltage comparison circuit capable of directly comparing various power source voltages.

An aspect of the present invention provides a voltage comparison circuit including:

a voltage adjustment section connected between a first potential supply line and a first node;

a first constant current source connected between the first node and a fixed potential supply line;

a switch element connected between a second potential supply line and a second node, and including a control terminal connected to the first node, the switch element operating in accordance with a voltage of the first node; and

a second constant current source connected between the second node and the fixed potential supply line.

According to the present invention, currents measuring voltages are inputted to the sources of MOS transistors. Thus, a useful effect is provided in that a voltage comparison circuit capable of directly comparing various power source voltages may be provided.

### BRIEF DESCRIPTION OF THE DRAWINGS

Exemplary embodiments of the present invention will be described in detail based on the following figures, wherein:

FIG. 1 is a circuit diagram showing an example of schematic structure of a voltage comparison circuit in accordance with a first exemplary embodiment of the present invention;

FIG. 2 is a graph showing output results of the first exemplary embodiment of the present invention;

FIG. 3 is a circuit diagram showing a variant example of the voltage comparison circuit in accordance with the first exemplary embodiment of the present invention;

FIG. 4 is a circuit diagram showing an example of schematic structure of a voltage comparison circuit in accordance with a second exemplary embodiment of the present invention;

FIG. 5 is a circuit diagram showing a variant example of the voltage comparison circuit in accordance with the second exemplary embodiment of the present invention; and

FIG. 6 is a circuit diagram showing an example of schematic structure of a commonly known voltage comparison circuit.

### DETAILED DESCRIPTION

### First Exemplary Embodiment

Herebelow, a voltage comparison circuit according to the present exemplary embodiment is described with reference to the attached drawings.

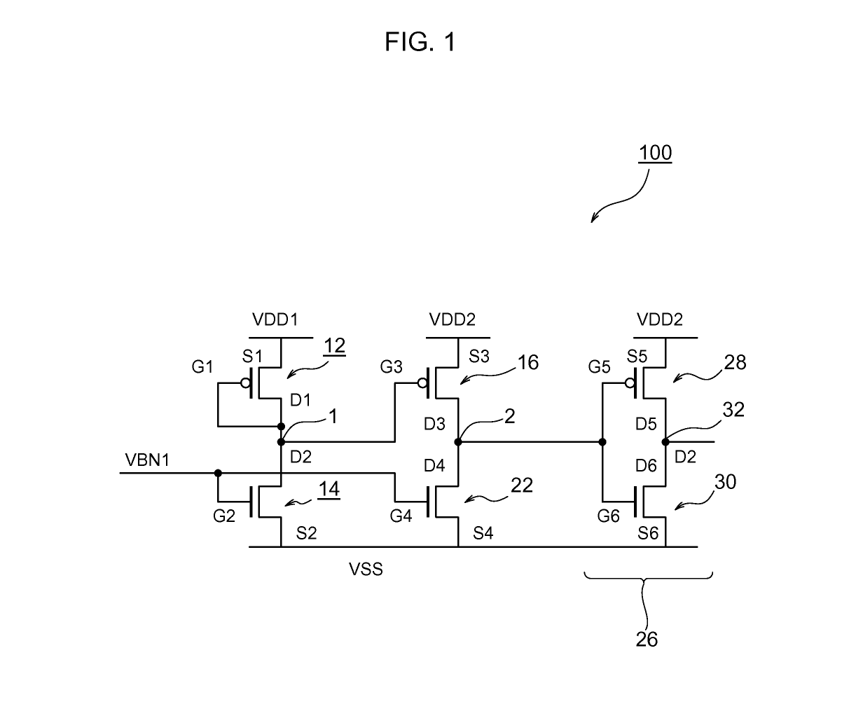

FIG. 1 shows an example of schematic structure of the voltage comparison circuit according to the present exemplary embodiment. A voltage comparison circuit 100 of the present exemplary embodiment that is illustrated in FIG. 1 is provided with a first PMOS transistor 12 in a front stage. A source 51 of the first PMOS transistor 12 is connected to a first power source, a power source voltage of which is VDD1, and a drain D1 and gate G1 are short-circuited together. Thus, the first PMOS transistor 12 is “diode-connected” and constituted to operate in the saturation region.

A first NMOS transistor 14 is also provided in the front stage of the voltage comparison circuit 100 of the present exemplary embodiment. A drain D2 of the first NMOS transistor 14 is connected with the drain D1 of the first PMOS transistor 12 at a node 1, a source S2 is connected to a ground potential VSS, and a gate G2 is provided with a bias voltage VBN1.

In a next stage, a second PMOS transistor 16 is provided. A source S3 of the second PMOS transistor 16 is connected to a second power source, a power source voltage of which is VDD2, and a gate G3 is connected with the drain D1 of the first PMOS transistor 12 at the node 1. The second PMOS transistor 16 has the same threshold voltage and current capacity as the first PMOS transistor 12.

A second NMOS transistor 22 is also provided in the next stage. A drain D4 of the second NMOS transistor 22 is connected with the drain D3 of the second PMOS transistor 16 at a node 2, a source S4 is connected to the ground potential VSS, and a gate G4 is provided with a bias voltage VBN1. The second NMOS transistor 22 has the same threshold voltage and current performance as the first NMOS transistor 14. The first NMOS transistor 14 and the second NMOS transistor 22 function as constant current sources.

A subsequent stage is a CMOS inverter 26 including an inverter PMOS transistor 28 and an inverter NMOS transistor 30. A gate G5 of the inverter PMOS transistor 28 is connected to the drain D3 of the second PMOS transistor 16, and a gate G6 of the inverter NMOS transistor 30 is also connected to the drain D3 of the second PMOS transistor 16.

In the CMOS inverter 26, the voltage VDD2 is provided to a source S5 of the inverter PMOS transistor 28, and a source S6 of the inverter NMOS transistor 30 is connected to the ground potential VSS. A drain D5 of the inverter PMOS transistor 28 and a drain D6 of the inverter NMOS transistor 30 are connected together, and a junction point of this connection serves as an output terminal 32.

Because the first PMOS transistor 12 provided in the front stage of the voltage comparison circuit 100 of the present exemplary embodiment is diode-connected and constituted to operate in the saturation region by the drain D1 and gate G1 being short-circuited, the gate-source voltage of the first PMOS transistor 12, VGS₁₂, is equal to the drain-source voltage, VDS₁₂.

The diode-connected first PMOS transistor 12 operates as a resistance element with a predetermined on-resistance, and functions as a voltage adjustment section that adjusts the voltage of node 1.

In the front stage of the voltage comparison circuit 100 of the present exemplary embodiment, the first PMOS transistor 12 and the first NMOS transistor 14 are connected in a complementary arrangement. Therefore, when saturation regions are formed in the first PMOS transistor 12 and the first NMOS transistor 14, the same current flows in the first PMOS transistor 12 and the first NMOS transistor 14.

In the next stage of the voltage comparison circuit 100 of the present exemplary embodiment, the second PMOS transistor 16 and the second NMOS transistor 22 are connected in a complementary arrangement. Therefore, when saturation regions are formed in the second PMOS transistor 16 and the second NMOS transistor 22, the same current flows in the second PMOS transistor 16 and the second NMOS transistor 22.

In the present exemplary embodiment, as mentioned above, because the drain D1 and gate G1 of the first PMOS transistor 12 are short-circuited, VGS₁₂=VDS₁₂.

Therefore, if the voltage of the drain D1 of the first PMOS transistor 12 is represented by VD₁, the gate-source voltage VGS₁₂ of the first PMOS transistor 12 can be expressed by the following expression (1).

VGS₁₂=VD₁−VDD1 (1)

Because the gate of the second PMOS transistor 16 is connected to the drain D1 of the first PMOS transistor 12, a gate-source voltage VGS₁₆ of the second PMOS transistor 16 can be expressed by the following expression (2).

VGS₁₆=VD₁−VDD2 (2)

If the threshold voltage of the first PMOS transistor 12 is represented by VT, a current Id₁₂ flowing in the first PMOS transistor 12, which is in the saturation region, can be found from the following expression (3) and expression (4).

Id₁₂=KₚW/L(VGS₁₂-VT)² (3)

Kₚ=½*μ*Cos (4)

In expression (3), W represents the width of an inversion layer and L represents the length of the inversion layer. In expression (4), μ represents the mobility of electrons and Cos represents a capacitance per unit area of the gate oxide layer.

If the aforementioned expression (1) is substituted into expression (3), the following expression (5) is obtained.

Id₁₂=KₚW/L(VDD1-VD₁+VT)² (5)

A current Id₁₆ flowing in the second PMOS transistor 16, which has the same threshold voltage as the first PMOS transistor 12 and is in the saturation region, can be found from the following expression (6).

Id₁₆=KₚW/L(VGS₁₆-VT)² (6)

If the aforementioned expression (2) is substituted into expression (6), the following expression (7) is obtained.

Id₁₆=KₚW/L(VDD2-VD₁+VT)² (7)

Thus, if VDD1>VDD2, the current Id₁₂ provided by expression (5) is greater than the current Id₁₆ provided by expression (7).

Therefore, a sufficient current does not flow in the second PMOS transistor 16, and a voltage VD₂₀ of the drain D3 of the second PMOS transistor 16 is lowered.

Alternatively, if VDD1<VDD2, the current Id₁₆ provided by expression (7) is greater than the current Id₁₂ provided by expression (5).

Sufficient current flows in the second PMOS transistor 16, and the voltage VD₂₀ of the drain D3 of the second PMOS transistor 16 is raised.

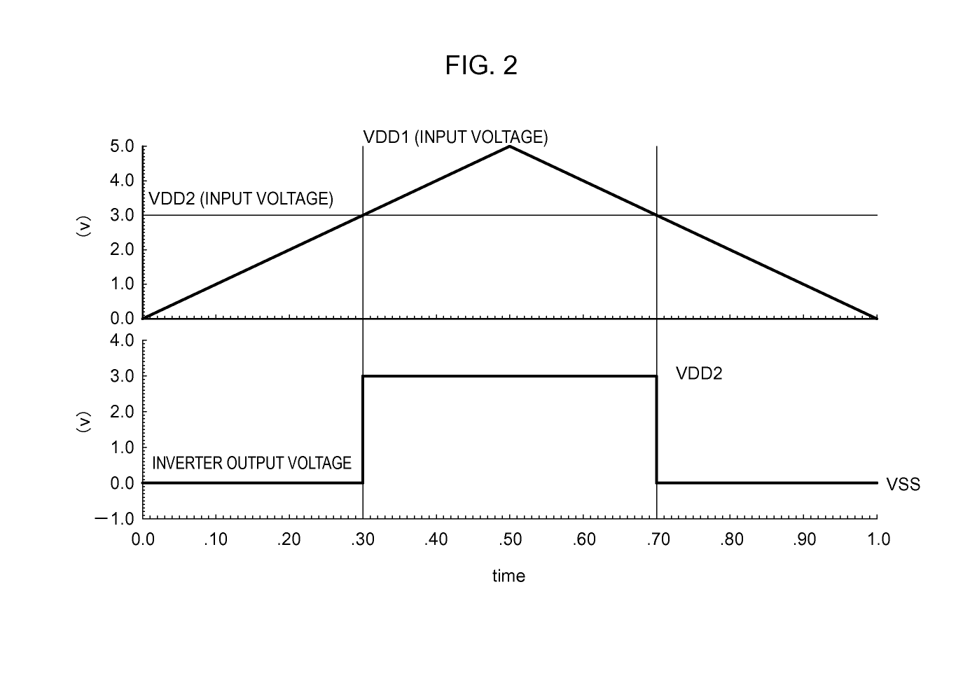

VD₂₀ is inputted to the CMOS inverter 26. Thus, output results as illustrated in FIG. 2 are obtained.

When VD₂₀is lowered, the inverter PMOS transistor 28 turns on, and VDD2 is outputted at the output terminal 32.

When VD₂₀ is raised, the inverter NMOS transistor 30 turns on, and the ground potential VSS of approximately 0 V is outputted at the output terminal 32.

Thus, the voltages of VDD1 and VDD2 may be compared by making a determination as to whether the voltage of the output terminal 32 is VDD2 or the ground potential VSS.

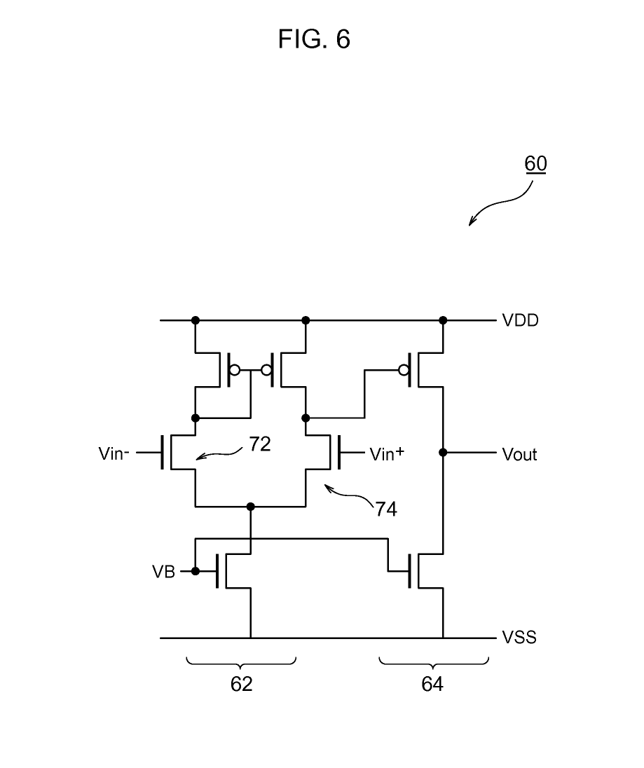

In the voltage comparison circuit 100 according to the present exemplary embodiment, because the number of components is smaller than in the common voltage comparison circuit illustrated in FIG. 6, the overall area of the circuit may be made smaller, and hence power consumption may be reduced and operation at a low voltage is possible. Moreover, because the number of components is small, the elements may be mounted close together. Thus, the effects of temperature changes on the components and the effects of variations in the performance of components may be reduced compared to the voltage comparison circuit 60 illustrated in FIG. 6.

The voltage comparison circuit 100 according to the present exemplary embodiment compares the voltages VDD1 and VDD2 on the basis of the current Id₁₂ flowing in the first PMOS transistor 12, as calculated by the aforementioned expression (5), and the current Id₁₆ flowing in the second PMOS transistor 16, as calculated by the aforementioned expression (7).

Provided the threshold voltages and current capacities of the first PMOS transistor 12 and the second PMOS transistor 16 are the same and the threshold voltages and current capacities of the first NMOS transistor 14 and the second NMOS transistor 22 are the same, voltages may be compared on the basis of the current Id₁₂ and the current Id₁₆. Therefore, even if there is a temperature change or a voltage fluctuation, the voltages of VDD1 and VDD2 may be compared with high accuracy.

While the present exemplary embodiment has the configuration illustrated in FIG. 1, in order to compare the voltages of VDD 1 and VDD2 with high accuracy, it is desirable to dispose the first PMOS transistor 12 and the second PMOS transistor 16 as close together as possible, and to dispose the first NMOS transistor 14 and the second NMOS transistor 22 as close together as possible.

If the voltage comparison circuit according to the present exemplary embodiment is implemented in an integrated circuit, variations in the components of the voltage comparison circuit according to the present exemplary embodiment may be restrained by suitable provision of dummy MOSs.

If feasible, variations in the components may be made to cancel out by the components being arranged in a common centroid layout.

The voltage comparison circuit 100 according to the present exemplary embodiment may also compare voltages other than power source voltages such as VDD1 and VDD2 or the like.

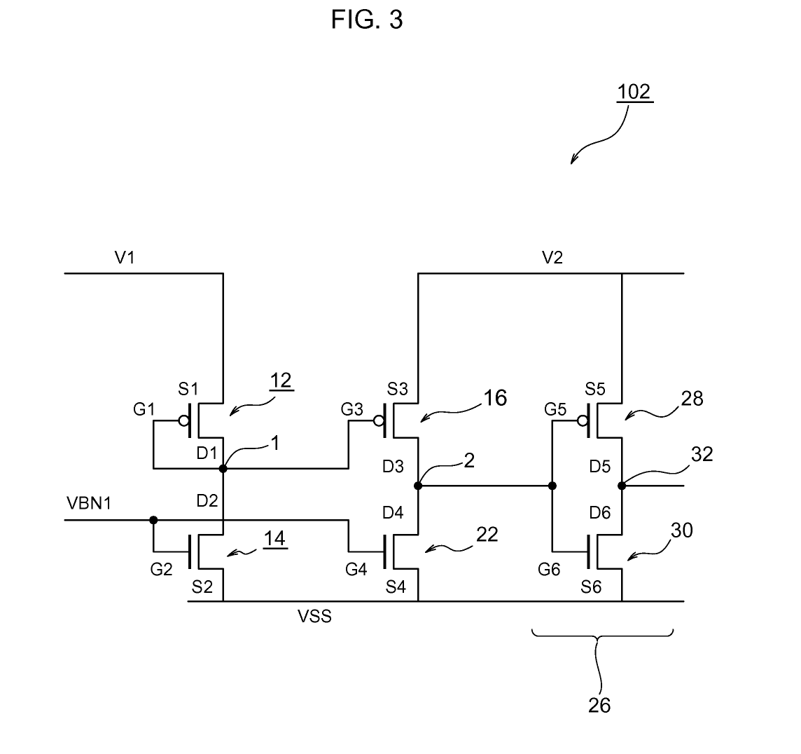

FIG. 3 is a diagram showing a variant example of the voltage comparison circuit according to the present exemplary embodiment.

In a voltage comparison circuit 102 illustrated in FIG. 3, a voltage V1 must be at least the sum of the voltage VD₁ of the drain D1 of the first PMOS transistor 12 and an overdrive voltage VOV₁₄ of the first NMOS transistor 14.

If the threshold voltage of the first PMOS transistor 12 is represented by VT, the voltage VD₁ of the first PMOS transistor 12 in which the saturation region is formed should be a voltage that is lower than V1 by VT±α. Here, a represents a change in measured VT associated with a change in a current flowing in the first NMOS transistor 14.

Therefore, the voltage V1 must satisfy the following expression (A).

V1>(VT±α)−VOV₁₄ (A)

Furthermore, for driving of the CMOS inverter 26 of the back stage to be possible, V2 must be at least a voltage capable of driving the CMOS inverter 26.

The meaning of the term “a voltage capable of driving the CMOS inverter 26” as used here includes a voltage that exceeds the larger threshold voltage of the respective threshold voltages of the inverter PMOS transistor 28 and inverter NMOS transistor 30 constituting the CMOS inverter 26.

According to the present exemplary embodiment and variant example as described hereabove, a voltage comparison circuit capable of directly comparing various power source voltages may be provided.

### Second Exemplary Embodiment

Herebelow, a voltage comparison circuit according to the present exemplary embodiment is described with reference to the attached drawings.

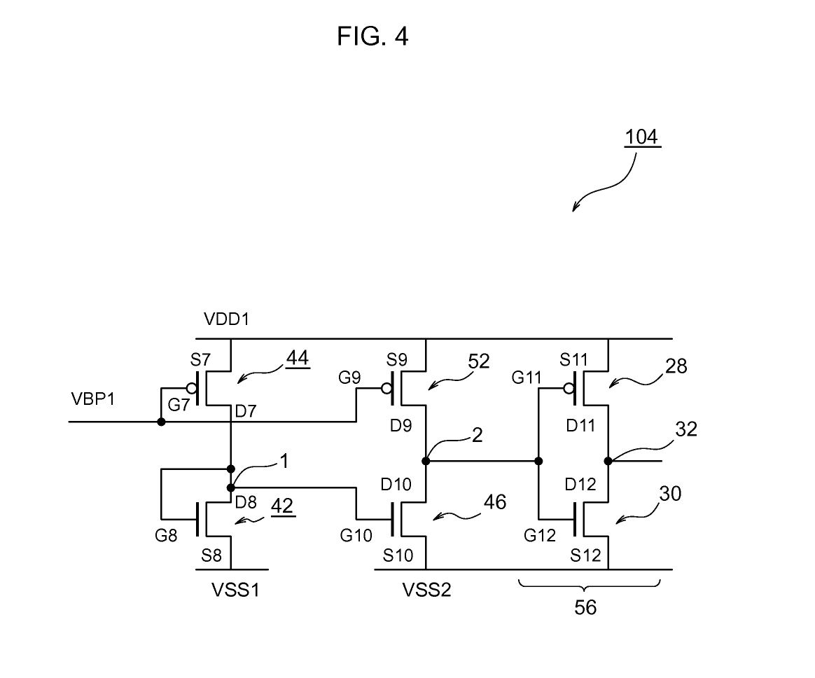

FIG. 4 shows an example of schematic structure of the voltage comparison circuit according to the present exemplary embodiment. A voltage comparison circuit 104 of the present exemplary embodiment that is illustrated in FIG. 4 has a structure in which the structure of the voltage comparison circuit 100 of the first exemplary embodiment is inverted.

In the voltage comparison circuit 104 of the present exemplary embodiment, the third NMOS transistor 42 is provided in the front stage. A source S8 of the third NMOS transistor 42 is connected to a ground potential VSS1 and a drain D8 and gate G8 are short-circuited together. Thus, the third NMOS transistor 42 is “diode-connected” and constituted to operate in the saturation region.

A third PMOS transistor 44 is also provided in the front stage of the voltage comparison circuit 104 of the present exemplary embodiment. A drain D7 of the third PMOS transistor 44 is connected with the drain D8 of the third NMOS transistor 42 at a node 1, a source S7 is connected to a power source, of which a power source voltage is VDD1, and a gate G7 is provided with a bias voltage VBP1.

A fourth NMOS transistor 46 is provided in the next stage. A source S10 of the fourth NMOS transistor 46 is connected to a ground potential VSS2 and a gate G10 is connected with the drain D8 of the third NMOS transistor 42 at node 1. The fourth NMOS transistor 46 has the same threshold voltage and current capacity as the third NMOS transistor 42.

A fourth PMOS transistor 52 is provided in the above-mentioned next stage. A drain D9 of the fourth PMOS transistor 52 is connected with the drain D10 of the fourth NMOS transistor 46 at a node 2, a source S9 is connected to the power source whose power source voltage is VDD1, and a gate G9 is provided with the bias voltage VBP1. The fourth PMOS transistor 52 has the same threshold voltage and current capacity as the third PMOS transistor 44.

The subsequent stage is a CMOS inverter 56 including the inverter PMOS transistor 28 and the inverter NMOS transistor 30. A gate G11 of the inverter PMOS transistor 28 is connected to the drain D10 of the fourth NMOS transistor 46, and a gate G12 of the inverter NMOS transistor 30 is also connected to the drain D10 of the fourth NMOS transistor 46.

The CMOS inverter 56 is the same as the CMOS inverter 26 of the voltage comparison circuit 100 of the first exemplary embodiment except that a source S11 of the inverter PMOS transistor 28 is connected to the power source whose power source voltage is VDD1 and a source S12 of the inverter NMOS transistor 30 is connected to the ground potential VSS2. Accordingly, detailed descriptions of the CMOS inverter 56 are not given.

In the front stage of the voltage comparison circuit 104 of the present exemplary embodiment, the third PMOS transistor 44 and the third NMOS transistor 42 are connected in a complementary arrangement. Therefore, when saturation regions are formed in the third PMOS transistor 44 and the third NMOS transistor 42, the same current flows in the third PMOS transistor 44 and the third NMOS transistor 42.

In the next stage of the voltage comparison circuit 104 of the present exemplary embodiment, the fourth PMOS transistor 52 and the fourth NMOS transistor 46 are connected in a complementary arrangement. Therefore, when saturation regions are formed in the fourth PMOS transistor 52 and the fourth NMOS transistor 46, the same current flows in the fourth PMOS transistor 52 and the fourth NMOS transistor 46.

In the present exemplary embodiment, because the drain D8 and gate G8 of the third NMOS transistor 42 are short-circuited, if the gate-source voltage of the third NMOS transistor 42 is represented by VGS₄₂ and the drain-source voltage of the third NMOS transistor 42 is represented by VDS₄₂, then VGS₄₂=VDS₄₂.

Therefore, if the voltage of the drain D8 of the third NMOS transistor 42 is represented by VD₈, the gate-source voltage VGS₄₂ of the third NMOS transistor 42 can be expressed by the following expression (8).

VGS₄₂=VD₈−VSS1 (8)

Because the gate G10 of the fourth NMOS transistor 46 is connected to the drain D8 of the third NMOS transistor 42 and the source S10 of the fourth NMOS transistor 46 is connected to the ground potential VS52, a gate-source voltage VGS₄₆ of the fourth NMOS transistor 46 can be expressed by the following expression (9).

VGS₄₆=VD₈−VSS2 (9)

If the threshold voltages of the third NMOS transistor 42 and the fourth NMOS transistor 46 are represented by Vt, a current Id₄₂ flowing in the third NMOS transistor 42, which is in the saturation region, can be found from the following expression (10).

Id₄₂=KₚW/L(VSS1−VD₈+Vt)² (10)

Similarly, a current Id₄₆ flowing in the fourth NMOS transistor 46, which is in the saturation region, can be found from the following expression (11).

Id₄₆=KₚW/L(VSS2−VD₈+Vt)² (11)

Thus, if VSS1<VSS2, the current Id₄₆ provided by expression (11) is greater than the current Id₄₂ provided by expression (10).

Sufficient current flows in the fourth NMOS transistor 46, and electrons, having negative charges, move from the source S10 of the fourth NMOS transistor 46 toward the drain D10. As a result, a voltage VD₁₀ of the drain D10 of the fourth NMOS transistor 46 is lowered.

Alternatively, if VSS1>VSS2, the current Id₄₂ provided by expression (10) is greater than the current Id₄₆ provided by expression (11).

A sufficient current does not flow in the fourth NMOS transistor 46, and sufficient electrons cannot move from the source S10 of the fourth NMOS transistor 46 toward the drain D10. As a result, the voltage VD₁₀ of the drain D10 of the fourth NMOS transistor 46 is higher than in the above-described case in which VSS1<VSS2.

The current outputted at the drain D10 is inputted to the CMOS inverter 56. If the voltage VD₁₀ of the drain D10 is raised, that is, if VSS1>VSS2, VSS2 is outputted from the output terminal 32. If the voltage VD₁₀ of the drain D10 is lowered, that is, if VSS1<VSS2, VDD1 is outputted from the output terminal 32.

According to the present exemplary embodiment as described above, a determination may be made as to which of the different VSS potentials is higher and which is lower.

The voltage comparison circuit 104 according to the present exemplary embodiment may compare voltages other than VSS1 and VSS2.

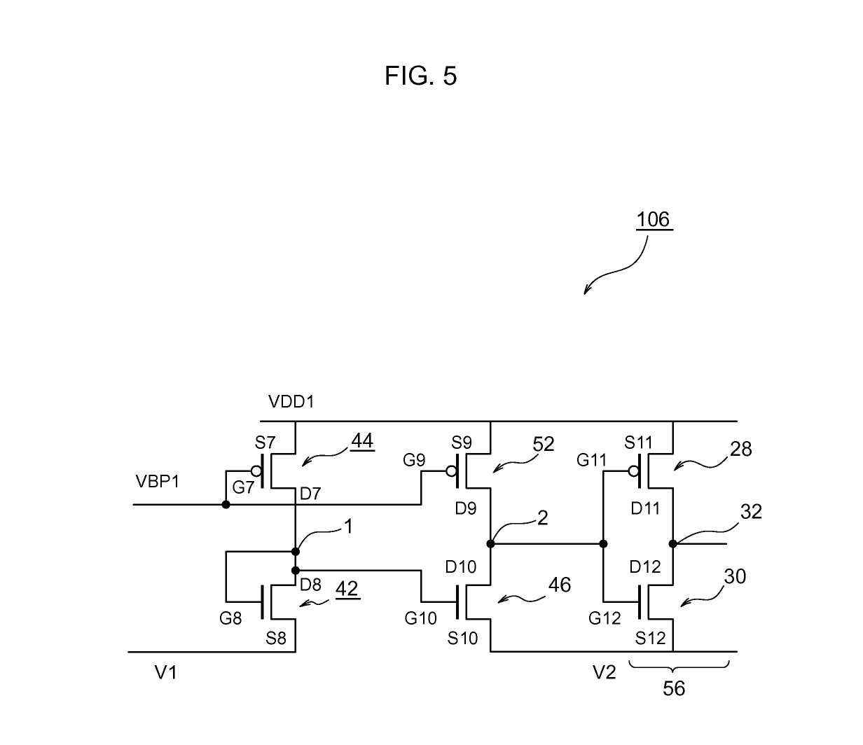

FIG. 5 is a diagram showing a variant example of the voltage comparison circuit according to the present exemplary embodiment.

In a voltage comparison circuit 106 illustrated in FIG. 5, if the voltage of the drain D8 of the third NMOS transistor 42 is represented by VD₈ and the overdrive voltage of the third PMOS transistor 44 is represented by VOV₄₄, the voltage VDD1-V1 must be at least VD₈+VOV₄₄.

If the threshold voltage of the third NMOS transistor 42 is represented by Vt, the voltage VD₈ of the third NMOS transistor 42 in which the saturation region is formed should be a voltage that is lower than VDD1 by Vt±α. Here, a represents a change in measured Vt associated with a change in the current flowing in the third NMOS transistor 42.

Therefore, the voltage V1 must satisfy the following expression (B).

V1>VDD1−(Vt±α)−VOV₄₄ (B)

Furthermore, for driving of the CMOS inverter 56 of the subsequent stage to be possible, the potential difference between VDD 1 and V2 must be at least a voltage capable of driving the CMOS inverter 56 provided at the subsequent stage.

The meaning of the term “a voltage capable of driving the CMOS inverter 56” as used here includes a voltage that exceeds the larger threshold voltage of the respective threshold voltages of the inverter PMOS transistor 28 and inverter NMOS transistor 30 constituting the CMOS inverter 56.

Therefore, if the larger value of the threshold voltages of the MOS transistors constituting the CMOS inverter 56 is represented by Vti, V2 must satisfy the following expression (C).

V2>VDD1−Vti (C)

As described hereabove, according to the present exemplary embodiment, the potential difference between the two voltages VSS may be determined, and hence the voltages of two power sources that serve as ground potentials may be determined.

It will be obvious to practitioners that the structures, operations and the like of the voltage comparison circuit 100, the voltage comparison circuit 102, the voltage comparison circuit 104, the voltage comparison circuit 106 and the like described in the present exemplary embodiments are merely examples, and that modifications may be applied in accordance with circumstances, within a scope not departing from the spirit of the present invention.

For example, although ordinary MOS transistors are used in the first exemplary embodiment and the second exemplary embodiment, a further improvement in accuracy may be expected if the components are connected in a cascode arrangement.

1. A voltage comparison circuit comprising:
a voltage adjustment section connected between a first potential supply line and a first node;
a first constant current source connected between the first node and a fixed potential supply line;
a switch element connected between a second potential supply line and a second node, and including a control terminal connected to the first node, the switch element operating in accordance with a voltage of the first node; and
a second constant current source connected between the second node and the fixed potential supply line.

2. The voltage comparison circuit according to claim 1, wherein the voltage adjustment section includes a first PMOS transistor, of which a source is connected to the first potential supply line, and a drain and gate are short-circuited, the first PMOS transistor being constituted so as to operate in a saturation region.

3. The voltage comparison circuit according to claim 1, wherein the switch element comprises a second PMOS transistor including:
a source to which the second potential supply line is connected; and
a gate that serves as the control terminal connected to the first node.

4. The voltage comparison circuit according to claim 1, wherein the voltage adjustment section and the switch element are disposed adjacent to one another.

5. The voltage comparison circuit according to claim 1, wherein the voltage adjustment section includes a first PMOS transistor, the switch element includes a second PMOS transistor, and the first PMOS transistor and second PMOS transistor are constituted such that threshold voltages and current capacities thereof are equal.

6. The voltage comparison circuit according to claim 1, wherein the first constant current source includes a first NMOS transistor, including a drain connected to the first node, a source connected to ground, and a gate to which a bias voltage is provided, and
the second constant current source includes a second NMOS transistor, including a drain connected to the second node, a source connected to ground, and a gate to which the bias voltage is provided.

7. The voltage comparison circuit according to claim 6, wherein the first NMOS transistor and second NMOS transistor are constituted such that threshold voltages and current capacities thereof are equal.

8. The voltage comparison circuit according to claim 1, wherein the voltage adjustment section comprises a third NMOS transistor, of which a source is connected to the first potential supply line, and a drain and gate are short-circuited, the third NMOS transistor being constituted so as to operate in a saturation region.

9. The voltage comparison circuit according to claim 1, wherein the switch element comprises a fourth NMOS transistor including:
a source to which the second potential supply line is connected; and
a gate that serves as the control terminal connected to the first node.

10. The voltage comparison circuit according to claim 8, wherein the voltage adjustment section and the switch element are disposed adjacent to one another.

11. The voltage comparison circuit according to claim 1, wherein the voltage adjustment section includes a third NMOS transistor, the switch element includes a fourth NMOS transistor, and the third NMOS transistor and fourth NMOS transistor are constituted such that threshold voltages and current capacities thereof are equal.

12. The voltage comparison circuit according to claim 1, wherein
the first constant current source includes a third PMOS transistor, including a drain connected to the first node, a source connected to a third potential supply line, and a gate to which a bias voltage is provided, and
the second constant current source includes a fourth PMOS transistor, including a drain connected to the second node, a source connected to the third potential supply line, and a gate to which the bias voltage is provided.

13. The voltage comparison circuit according to claim 12, wherein the third PMOS transistor and the fourth PMOS transistor are constituted such that threshold voltages and current capacities thereof are equal.
